(19) United States
(12) Patent Application Publication
(10) Pub. No.: US 2008/0142996 A1
(43) Pub. Date: Jun. 19, 2008

(54) Controlling flow of underfill using polymer coating and resulting devices

(76) Inventors: Gopalakrishnan Subramanian, Chandler, AZ (US); Nirupama Chakrapani, Chandler, AZ (US); Lawrence D. Decesare, Chandler, AZ (US); Shripad Gokhale, Chandler, AZ (US); Jason M. Murphy, Chandler, AZ (US); Jinlin Wang, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/641,638

(22) Filed: Dec. 19, 2006

(51) Int. Cl. H01L 23/31; H01L 21/71

(52) U.S. Cl. 257/788; 438/127; 257/E23.116; 257/E21.536

(57) ABSTRACT

According to one embodiment, a polymer coating is disposed on a surface of a package substrate. The polymer coating comprises a material capable of inhibiting the flow of an underfill material into a keep-out zone (KOZ). In a further embodiment, a die is disposed on the substrate and a layer of the underfill material is disposed between the die and substrate, and the polymer coating inhibits the flow of the underfill into the KOZ. Other embodiments are described and may be claimed.

### FIELD OF THE INVENTION

The disclosed embodiments relate generally to the manufacture of integrated circuit devices, and more particularly to controlling the flow of an underfill material over the surface of a substrate.

### BACKGROUND OF THE INVENTION

To package an integrated circuit (IC) die, the die is typically disposed on one surface of a substrate and electrically coupled with the substrate. By way of example, for a flip chip attachment process, an array of electrically conductive terminals on the die (e.g., metal bumps or columns) is coupled with a mating array of electrically conductive terminals on the substrate (e.g., metal pads or lands, solder bumps, etc.) to form a number of interconnects extending between the die and substrate. The substrate includes a number of electrically conductive terminals (e.g., metal bumps, columns, pins, etc.) on an opposing surface to electrically couple the package with a next-level component, such as a printed circuit board (e.g., a motherboard).

Both the interconnects attaching the IC die to the substrate and an interconnect structure (which may include a low-k dielectric material) formed over the active surface of the die may be susceptible to cracking or other failures resulting from thermally induced stresses and warpage. To improve the robustness of the above-described electrical (and mechanical) coupling between the die and substrate, as well as to minimize the effects of thermally induced stresses and warpage, a layer of an underfill material (e.g., an epoxy) may be disposed between the IC die and substrate. A common method to dispense an underfill material under a flip-chip mounted die is to dispense the underfill along one edge (or multiple edges) of the IC die and utilize capillary flow to draw the underfill into the space between the die and substrate. To achieve the desired capillary flow, a low viscosity underfill material may be used and/or the underfill may be heated to lower its viscosity. Due, at least in part, to this low viscosity, a “tongue” of underfill material may be created on the substrate surface adjacent the die.

The surface area of a substrate reserved for the mounting of other components (e.g., capacitors and other passive devices, other IC devices, etc.), or more generally that portion of the substrate surface where underfill flow is undesired, may be referred to as the keep-out zone (KOZ). The aforementioned underfill “tongue” remaining on the substrate can limit the KOZ, necessitating the use of a larger substrate to allow for formation of the tongue. However, for small form factor packages, as well as other packages, it may be desirable to use a smaller substrate to minimize the package's footprint. Thus, controlling the flow of underfill material on the substrate surface and maintaining the boundaries of the KOZ may be important considerations in the manufacture of small form factor packages. The ability to maintain the KOZ can enable the use of smaller substrates, as well as the closer spacing of IC die and/or other components (e.g., passives) on the substrate.

### BRIEF DESCRIPTION OF THE DRAWINGS

FIG. 1A is a schematic diagram illustrating an embodiment of a package substrate having a polymer coating to control the flow of an underfill material.

FIG. 1B is a schematic diagram illustrating another embodiment of a package substrate having a polymer coating to control the flow of an underfill material.

FIGS. 2A and 2B are schematic diagrams illustrating embodiments of an assembly including the substrate of FIG. 1A (or FIG. 1B).

FIG. 3 is a block diagram illustrating an embodiment of a method of forming a polymer coating on a substrate to control the flow of underfill.

### DETAILED DESCRIPTION OF THE INVENTION

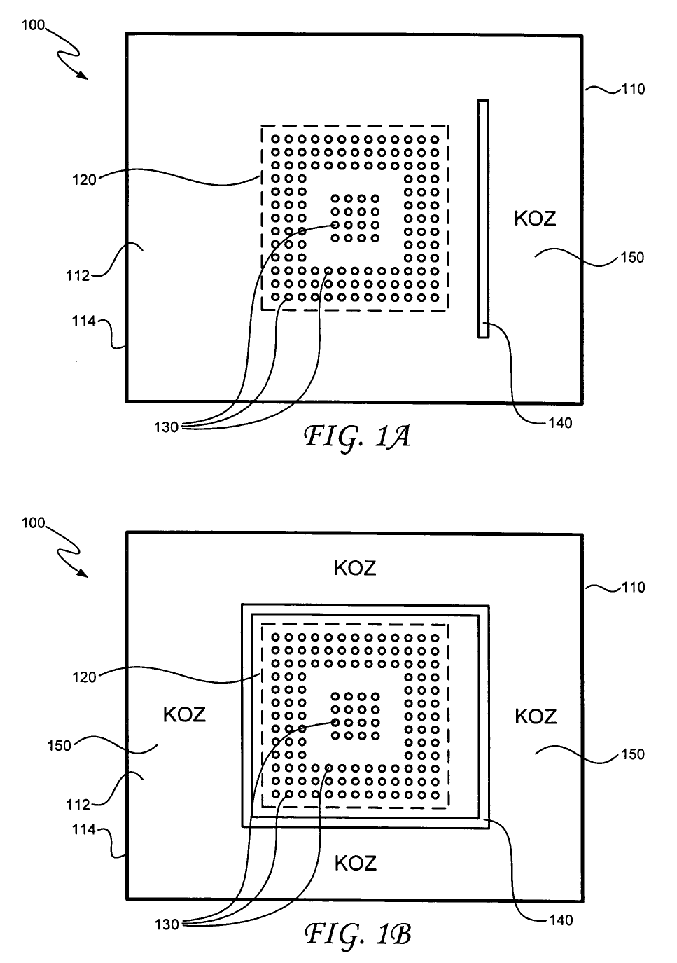

Illustrated in FIG. 1A is an embodiment of a package substrate 100 (or other die carrier). The package substrate 100 includes a surface having a polymer coating disposed thereon, and this polymer coating can control the flow of an underfill material and, hence, inhibit the flow of the underfill material into a keep-out zone (KOZ) on the substrate surface. By inhibiting underfill flow into the KOZ, the size of any underfill “tongue” that is formed can be minimized and the boundaries of the KOZ maintained, which may be beneficial for small form factor packages.

Referring to FIG. 1A, the package substrate 100 comprises a substrate 110. In one embodiment, the substrate 110 comprises a multilayer substrate including a number of alternating layers of metallization and dielectric material. Each layer of metallization comprises a number of conductors (e.g., traces), and these conductors may comprise any suitable conductive material, such as copper or a copper alloy. Further, each metal layer is separated from adjacent metal layers by the dielectric layers, and adjacent metal layers may be electrically interconnected by conductive vias. The dielectric layers may comprise any suitable insulating material—e.g., polymers, including both thermoplastic and thermosetting resins or epoxies, ceramics, etc.—and the alternating layers of metal and dielectric material may be built-up over a core layer of a dielectric material (or perhaps a metallic core). The substrate 110 includes a first side 112 and an opposing second side 114.

On the first side 112 of substrate 110, a die region 120 is provided. An integrated circuit (IC) die may be mounted on the package substrate 100 within the die region 120. Disposed within the die region 120 on the substrate first surface 112 is a number of electrically conductive terminals 130. According to one embodiment, the electrically conductive terminals 130 comprises an array of pads or lands that are arranged to mate with a corresponding array of terminals formed on an IC die that is to be flip-chip mounted on the package substrate 100. In this embodiment, the conductive terminals 130 may comprise copper (or a copper alloy or other metal) pads, and in a further embodiment solder bumps may be disposed on these copper pads (and the mating terminals on the IC die may, in one embodiment, comprise copper or other metal bumps or columns electrically coupled with the terminals 130 by, for example, a reflow process). It should be understood, however, that the disclosed embodiments are not limited to substrates adapted for flip-chip bonding and, further, that the electrically conductive terminals 130 may comprise any other type of terminal or element that may be used to form an electrical connection with an IC device (e.g., bond pads for wirebonding, etc.).

In another embodiment, a number of electrically conductive terminals (not shown in figures) may also be disposed on the substrate's opposing second side 114. The conductive terminals on the substrate's second side 114 may comprise metal bumps, columns, pins, etc., and these terminals may be used to electrically couple the package substrate 100 with a next-level component (e.g., a motherboard or other a printed circuit board, etc.).

Disposed on the first side 112 of substrate 110 is a polymer layer or coating 140. The polymer coating 140 comprises any polymer capable of impeding or inhibiting the flow of an underfill material. In one embodiment, the polymer coating 140 is arranged in a pattern that defines a keep-out zone (KOZ) or that otherwise prevents (or at least inhibits) the flow of underfill into the KOZ. For example, as shown in FIG. 1A, the polymer coating 140 is arranged in a single bead or line that defines (at least in part) a KOZ 150. It should be noted that other features (or devices) on the substrate may also play a role in defining the extent of the KOZ 150 (e.g., the edges of the substrate 110, an IC die disposed on the substrate 110, passive devices disposed on the substrate first surface 112, etc.).

In the embodiment of FIG. 1A, the polymer coating 140 was arranged in a single line or bead along one edge of the die region 120. However, it should be understood that the polymer coating 140 may be arranged in any desired pattern. By way of example, referring to FIG. 1B, in one embodiment the polymer coating 140 may be arranged in a pattern that fully surrounds (or at least substantially surrounds) a perimeter of the die region 120. In the embodiment of FIG. 1B, the polymer coating 140 again inhibits the flow of underfill into (and at least partially defines) a KOZ 150. Other patterns of the polymer coating in addition to the examples shown in FIGS. 1A and 1B are possible, and the pattern that is used may be a function of several factors (e.g., the package form factor, die size, underfill viscosity, the process flow, etc.).

As noted above, the polymer coating 140 may comprise any polymer capable of at least partially impeding the flow of an underfill material. In one embodiment, the polymer coating comprises a material that is non-wetting with respect to an underfill material. In another embodiment, the polymer coating 140 comprises a material having a surface energy in a range of approximately 6 mN/m to 20 mN/m. In a further embodiment, the polymer coating 140 comprises any polymer material that provides a contact angle greater than (or equal to) approximately 90 degrees. Also, in yet another embodiment, one or more properties of the polymer coating 140 may be altered by a thermal treatment. For example, a thermal treatment may be performed to cross-link the polymer, to alter the surface energy and/or contact angle (or to otherwise alter the wetting behavior), to alter another aspect of the polymer's surface chemistry, etc. According to one embodiment, the polymer coating 140 comprises a fluoropolymer. However, it should be understood that other polymer materials may also find application to the disclosed embodiments.

The polymer coating 140 may be disposed on the substrate 110 using any suitable process. For example, in one embodiment, the polymer material may be dispensed on the substrate using a needle. The needle dispenser can be moved relative to the substrate to trace out the desired pattern of polymer. In another embodiment, a pattern of the polymer material may be formed on the substrate by stencil printing. In a further embodiment, a pattern of the polymer material may be created by forming a mask over the substrate and then applying a layer of the polymer material by spin coating (or other blanket deposition technique). As the reader will appreciate, other processes and/or devices may be used to form the desired pattern of polymer material on the substrate. In one embodiment, the polymer may be dispensed in a solution including a solvent (e.g., a fluoropolymer in a solution including a fluorosolvent).

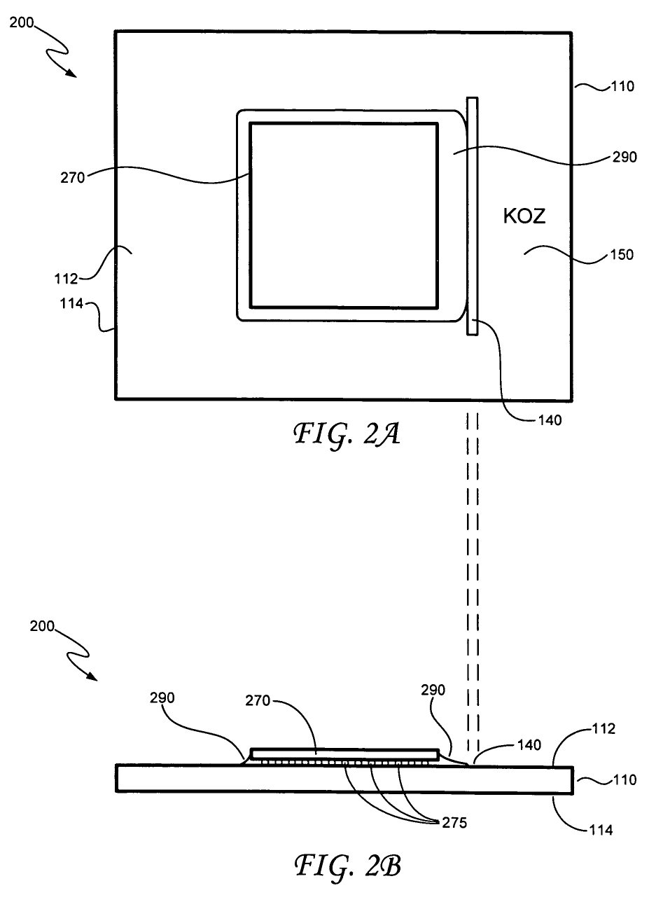

Referring now to FIGS. 2A and 2B, illustrated is an embodiment of an assembly 200 including the package substrate 100 of FIG. 1A (or FIG. 1B). A top plan view of the assembly 200 is shown in FIG. 2A, whereas a side elevation view of the assembly is shown in FIG. 2B.

With reference to FIGS. 2A and 2B, the assembly 200 includes the package substrate 100 described above. Disposed on the substrate 100 is an IC die 270. In one embodiment, the IC die 270 comprises a processing device, such as a microprocessor, a graphics processor, an application specific integrated circuit (ASIC), a field programmable gate array (FPGA), etc. It should, however, be understood that other types of integrated circuit devices may be disposed on the substrate 100 (e.g., a wireless communications device, a chip set, a MEMS device, a memory controller, a memory device, etc.). A number of electrically conductive terminals (e.g., copper or other metal bumps or columns) on IC die 270 are electrically (and perhaps mechanically) coupled with a number of terminals 130 (e.g., copper or other metal lands or pads, perhaps having a solder bump formed thereon) to form a plurality of electrical interconnects 275 extending between the die 270 and substrate 100. A reflow process may be used to form the electrical interconnects 275 (which, for ease of illustration, are shown in solid line in FIG. 2B). The disclosed embodiments are not limited to flip-chip bonding, and other types of interconnects (e.g., wirebonds) may be formed between the die 270 and substrate 100.

After (or, alternatively, prior to) formation of the interconnects 275, an underfill material 290 is disposed between the IC die 270 and substrate 100. In one embodiment, the underfill layer 290 forms a mechanical bond between the IC die 270 and substrate 100 In another embodiment, the underfill layer 290 provides support to, and increases the strength of, the interconnects 275. The underfill 290 may comprise any material capable of performing one or more of the above-described as well as other functions. In one embodiment, the underfill material 290 comprises an epoxy. Typically, the underfill material 290 would be dispensed onto the substrate in a region between the polymer coating 140 and the adjacent edge of the IC die 270, and the underfill material flows between the IC die and substrate 110 due to capillary flow.

As shown in FIGS. 2A and 2B, the polymer coating 140 inhibits the flow of the underfill 290. For example, in the illustrated embodiment, the underfill material 290 flows across the substrate surface 112 up to the polymer coating 140, but the underfill does not cross over the polymer coating into the KOZ 150. By controlling the flow of the underfill 290 using polymer coating 240, the size of any underfill “tongue” is minimized and the boundaries of the KOZ are maintained.

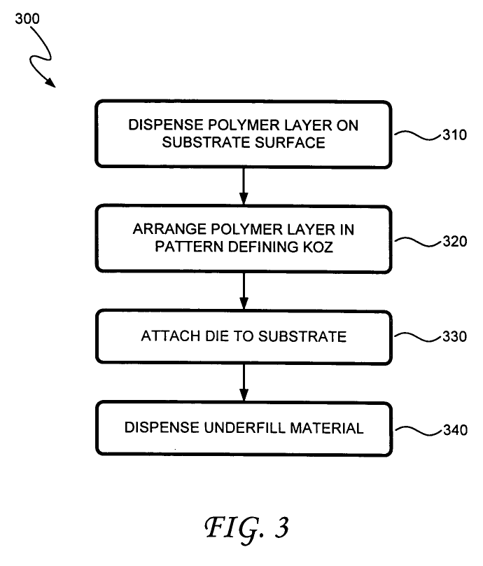

Turning to FIG. 3, illustrated is an embodiment of a method 300 for forming a polymer coating on a substrate to control the flow of underfill. Referring to block 310, a polymer material is dispensed on a surface of a substrate (see FIGS. 1A-1B and the accompanying text above). As set forth in block 320, the polymer material is arranged in a pattern defining (at least in part) a keep-out zone (again, see FIGS. 1A-1B and the accompanying text above). In one embodiment, as previously noted, a thermal treatment may be performed to alter a characteristic of the polymer coating. In another embodiment, as set forth in block 330, an IC die may be attached to the substrate (see FIGS. 2A-2B and the accompanying text above). With reference to block 340, an underfill material may be disposed between the IC die and substrate (again, see FIGS. 2A-2B and the accompanying text above). The polymer coating may assist in controlling the flow of the underfill material (e.g., inhibiting the flow of the underfill into the KOZ), as described above.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. An apparatus comprising:
a substrate, the substrate including a surface having a die region; and
a polymer coating disposed on the substrate surface proximate at least one side of the die region, the polymer coating to inhibit the flow of an underfill material.

2. The apparatus of claim 1, wherein the polymer coating comprises a fluoropolymer.

3. The apparatus of claim 1, wherein the polymer coating provides a surface energy in a range of approximately 6 mN/m to 20 mN/m.

4. The apparatus of claim 1, wherein the polymer coating provides a contact angle greater than approximately 90 degrees.

5. The apparatus of claim 1, wherein the polymer coating is arranged in a pattern at least partially defining a keep-out zone (KOZ).

6. The apparatus of claim 1, further comprising:
an integrated circuit (IC) die disposed on the substrate in the die region, the IC die including a number of electrically conductive terminals coupled with a number of electrically conductive terminals on the substrate; and
a layer of the underfill material disposed between the IC die and the substrate surface.

7. The apparatus of claim 1, wherein the polymer coating substantially surrounds a perimeter of the die region.

8. A method comprising:
depositing a layer of a polymer material onto a surface of a substrate;
wherein the polymer layer is arranged in a pattern at least partially defining a keep-out zone (KOZ), the polymer layer to inhibit the flow of an underfill material into the KOZ.

9. The method of claim 8, further comprising:
electrically coupling an integrated circuit die to the substrate surface; and
dispensing a layer of the underfill material between the IC die and the substrate surface, wherein the KOZ is substantially free of the underfill material.

10. The method of claim 8, wherein the polymer material comprises a fluoropolymer.

11. The method of claim 8, wherein the polymer material provides a surface energy in a range of approximately 6 mN/m to 20 mN/m.

12. The method of claim 8, wherein the polymer material provides a contact angle greater than approximately 90 degrees.

13. The method of claim 8, further comprising performing a thermal treatment to alter at least one surface property of the polymer layer.

14. The method of claim 8, wherein the polymer coating substantially surrounds a perimeter of the die region.
